(19) United States
(12) Patent Application Publication
(10) Pub. No.: US 2025/0218779 A1
(43) Pub. Date: Jul. 3, 2025

(54) EPITAXIAL STRUCTURE FOR SEMICONDUCTOR DEVICES AND METHOD FORMING THEREOF

(71) Applicant: Taiwan Semiconductor Manufacturing Company, Ltd., Hsin-Chu (TW)

(72) Inventors: Shih-Hao Lin, Hsinchu (TW); Jui-Lin Chen, Taipei City (TW); Chih-Hsiang Huang, Zhubei City (TW)

(21) Appl. No.: 18/656,666

(22) Filed: May 7, 2024

Related U.S. Application Data
(60) Provisional application No. 63/615,620, filed on Dec. 28, 2023.

(51) Int. Cl. H01L 21/266; H01L 29/06; H01L 29/417; H01L 29/423; H01L 29/66; H01L 29/775; H01L 29/786

(52) U.S. Cl. CPC H01L 21/266; H10D 30/014; H10D 30/43; H10D 30/6735; H10D 30/6757; H10D 62/121; H10D 64/017; H10D 64/018; H10D 64/258

(57) ABSTRACT

The present disclosure provides a semiconductor device and a method of forming the same. A method according one embodiment of the present disclosure includes forming a stack of channel layers interleaved by sacrificial layers, patterning the stack to form a fin-shape structure, forming a dummy gate stack over a channel region of the fin-shape structure, recessing a source/drain region to form a source/drain trench, forming an epitaxial feature in the source/drain trench, after the forming of the epitaxial feature removing the dummy gate stack, releasing the channel layers in the channel region as channel members, forming a gate structure wrapping around each of the channel members, and after the forming of the gate structure performing an ion implantation to increase a dopant concentration of a dopant in the epitaxial feature.

### PRIORITY DATA

This application claims priority to U.S. Provisional Patent Application No. 63/615,620, filed on Dec. 28, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e.., the number of interconnected devices per chip area) has generally increased while geometry size (i.e.., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as IC technologies progress towards smaller nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend around a channel region to provide access to the channel region on all four sides.

To improve performance of a GAA transistor, efforts are invested to develop epitaxial features that strain channels and provide reduced resistance. While conventional epitaxial features are generally adequate to their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2, 3, 4, 5, 6, 7, 8, 9, 10, 11, 12, 13, 14, 15, 16, 17, 18, 19, 20, 21, 22, 23, 24, 25, 26, 27, 28, 29, and 30 illustrate fragmentary cross-sectional views of a workpiece during a fabrication process according to the method of FIG. 1, according to one or more aspects of the present disclosure.

FIG. 31 illustrates a phosphorus concentration profile over a range of depths in source/drain features, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally related to multi-gate transistors and fabrication methods, and more particularly to dopant implantation in source/drain features of GAA transistors.

Channel regions of a GAA transistor may be disposed in nanowire channel members, bar-shaped channel members, nanosheet channel members, nanostructure channel members, column-shaped channel members, post-shaped channel members, and/or other suitable channel configurations. Depending on the shapes of the channel members, GAA transistors may also be referred to as nanowire transistors or nanosheet transistors. Despite the shapes, each of the channel members of a GAA transistor extend between and are coupled to two epitaxial features in two opposing source/drain regions. The epitaxial features are also referred to as source/drain features or source/drain epitaxial features. Source/drain region(s) may refer to a source or a drain, individually or collectively dependent upon the context.

The source/drain features of a GAA transistor are generally implanted with dopants to provide low resistance. For example, source/drain features of an n-type field effect transistor (FET) are doped with n-type dopants such as phosphorus (P) or arsenic (As), and source/drain features of a p-type FET are doped with p-type dopants such as boron (B) or gallium (Ga). Generally, a higher concentration of dopants in the source/drain features leads to a lower resistance. Yet, the amount of dopants to be implanted into the source/drain features has to be balanced with other design considerations. For example, in a gate replacement process during the formation of a GAA transistor, phosphorus (P) as a dopant having a high solubility may diffuse into a region between channel members and inner spacers and induce metal gate extrusion through this region. When metal gate extrusion occurs, device performance deteriorates, and yield rate drops.

The present disclosure provides embodiments of a semiconductor device where an extra dopant implantation is performed after the gate replacement process to introduce a high concentration of phosphorus into the source/drain features to lower resistance in the source/drain regions. Since the metal gate is already formed after the gate replacement process, an increase of the phosphorus concentration in the source/drain features would not cause a metal gate extrusion.

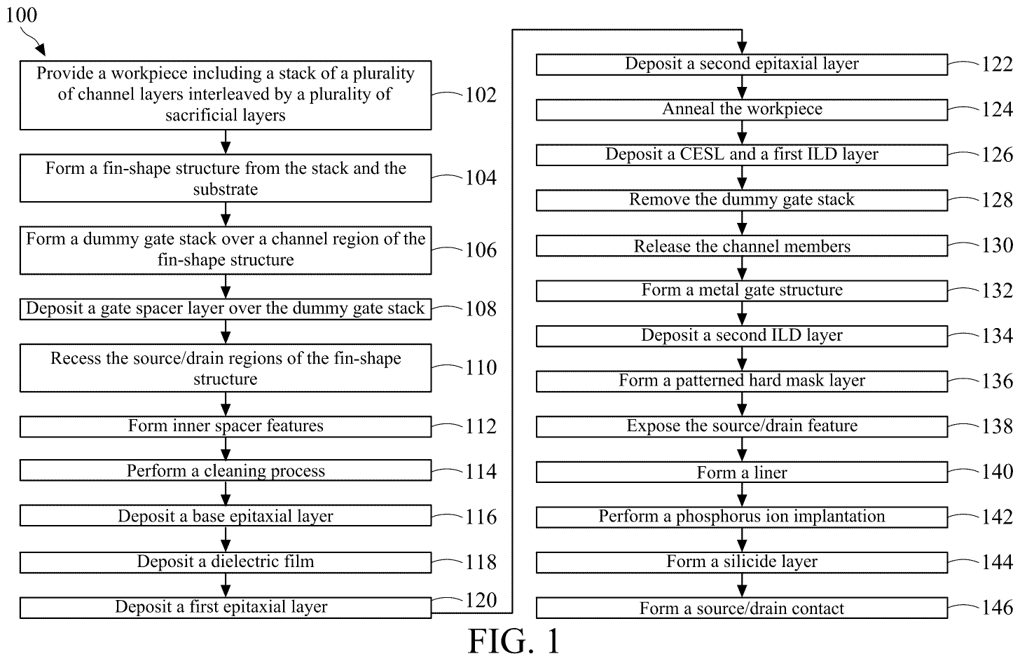

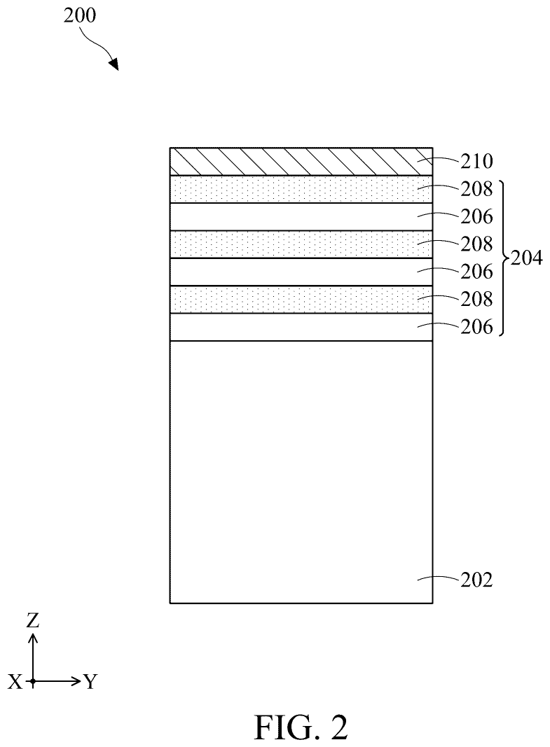

The various aspects of the present disclosure will now be described in more detail with reference to the figures. In that regard, FIG. 1 is a flowchart illustrating a method 100 of forming a semiconductor device from a workpiece according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 2-30, which are fragmentary cross-sectional views of workpiece 200 at different stages of fabrication according to embodiments of the method 100 in FIG. 1. Because the workpiece 200 will be fabricated into a semiconductor device, the workpiece 200 may be referred to herein as a semiconductor device 200 as the context requires. For avoidance, the X, Y and Z directions in FIGS. 2-30 are perpendicular to one another. Throughout the present disclosure, like reference numerals denote like features, unless otherwise excepted.

Referring to FIGS. 1 and 2, method 100 includes a block 102 where a stack 204 of alternating semiconductor layers is formed over the workpiece 200. As shown in FIG. 2, the workpiece 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P) or arsenide (As). In embodiments where the semiconductor device is n-type, a p-type doping profile (i.e., a p-type well or p-well) may be formed on the substrate 202. In some implementations, the n-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 includes sacrificial layers 206 of a first semiconductor composition interleaved by channel layers 208 of a second semiconductor composition. The first and second semiconductor composition may be different. In some embodiments, the sacrificial layers 206 include silicon germanium (SiGe) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 1 and 20.

In some embodiments, all sacrificial layers 206 may have a substantially uniform first thickness between about 3 nm and about 10 nm and all of the channel layers 208 may have a substantially uniform second thickness between about 3 nm and about 15 nm. The first thickness and the second thickness may be the same or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance between adjacent channel region(s) for a subsequently-formed multi-gate device and the thickness of each of the sacrificial layers 206 is chosen based on device performance considerations.

The layers in the stack 204 may be deposited using a molecular beam epitaxy (MBE) process, a vapor phase deposition (VPE) process, and/or other suitable epitaxial growth processes. Therefore, the stack 204 is also referred to as the epitaxial stack 204. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free, where for example, no intentional doping is performed during the epitaxial growth processes for the stack 204. In some implementations, the top surface of the substrate 202 is in a (100) crystalline plane, and accordingly each layer of the stack 204 has a (100) top surface. In some alternative implementations, the top surface of the substrate is in a (110) crystalline plane, and accordingly each layer of the stack 204 has a (110) top surface.

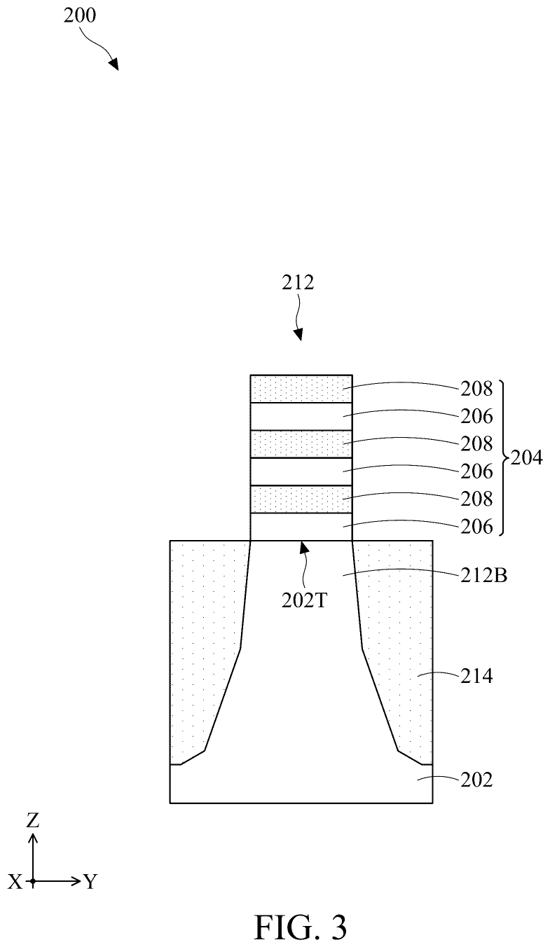

Referring to FIGS. 1, 2, and 3, method 100 includes a block 104 where a fin-shape structure 212 is formed from patterning the stack 204 and the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer over the pad oxide layer. The fin-shape structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending through the stack 204 and a portion of the substrate 202. The trenches define the fin-shape structures 212. In some implementations, double-patterning or multi-patterning processes may be used to define fin-shape structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shape structure 212 by etching the stack 204 and a top portion of the substrate 202. The patterned top portion of the substrate 202 is also denoted as a fin-shape base 212B. A horizontal plane comprising an interface between the stack 204 and the fin-shape base 212B is denoted as the plane 202T, which marks a position of the bottom surface of the stack 204 and/or the top surface of the fin-shape base 212B. The fin-shape base 212B may still be considered as a top part of the substrate 202 as the context requires. Therefore, the plane 202T may also be considered as marking a position of the top surface of the substrate 202. As shown in FIG. 3, the fin-shape structure 212, which includes the patterned stack 204 and the fin-shape base 212B, extends vertically along the Z direction and lengthwise along the X direction. In some instances, the fin-shape structure 212 measures between about 6 nm and about 80 nm wide along the Y direction, and a distance between opposing sidewalls of two adjacent fin-shape structures 212 measures between about 6 nm and about 115 nm along the Y direction.

An isolation feature 214 is formed adjacent the fin-shape structure 212. In some embodiments, the isolation feature 214 may be formed in the trenches to isolate the fin-shape structures 212 from a neighboring active region. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214. The fin-shape structure 212 rises above the STI feature 214 after the recessing. The recessed top surface of the STI feature 214 may be leveled with the plane 202T or below the plane 202T.

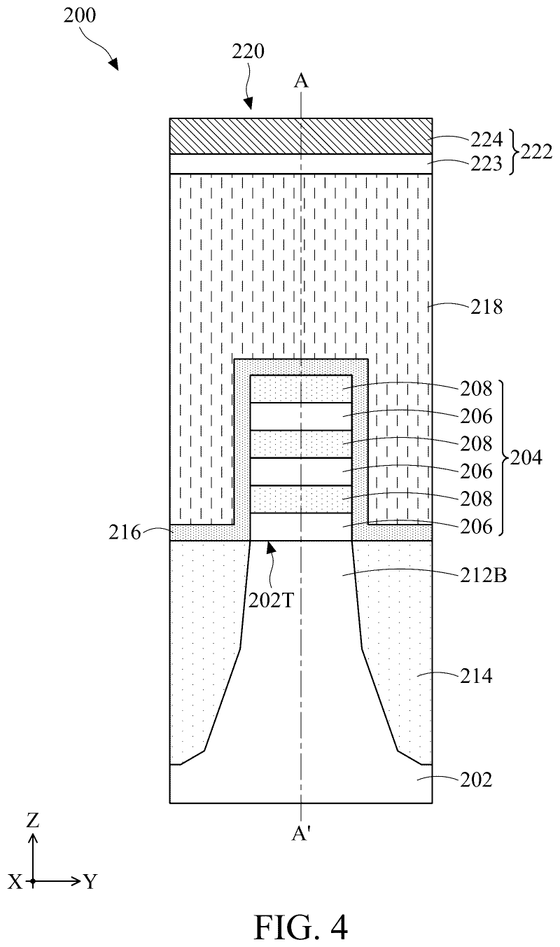

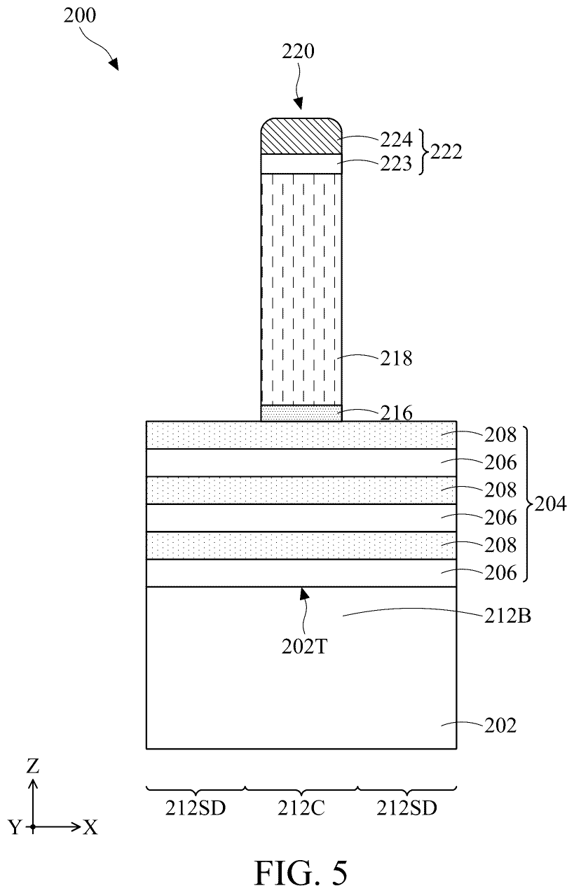

Referring to FIGS. 1, 4, and 5, method 100 includes a block 106 where a dummy gate stack 220 is formed over a channel region 212C of the fin-shape structure 212. FIG. 5 is a cross-sectional view cut through A-A′ line in FIG. 4. In some embodiments, a gate replacement process (or gate-last process) is adopted where the dummy gate stack 220 (shown in FIGS. 4 and 5) serves as a placeholder to undergo various processes and is to be removed and replaced by the functional gate structure. Other processes and configuration are possible. In some embodiments illustrated in FIG. 5, the dummy gate stack 220 is formed over the fin-shape structure 212 and the fin-shape structure 212 may be divided into channel regions 212C underlying the dummy gate stacks 220 and source/drain regions 212SD that do not underlie the dummy gate stacks 220. The channel regions 212C are adjacent the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the workpiece 200. In some embodiments, the dummy dielectric layer 216 may be formed on the fin-shape structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, no dummy gate stack 220 is disposed over the source/drain region 212SD of the fin-shape structure 212.

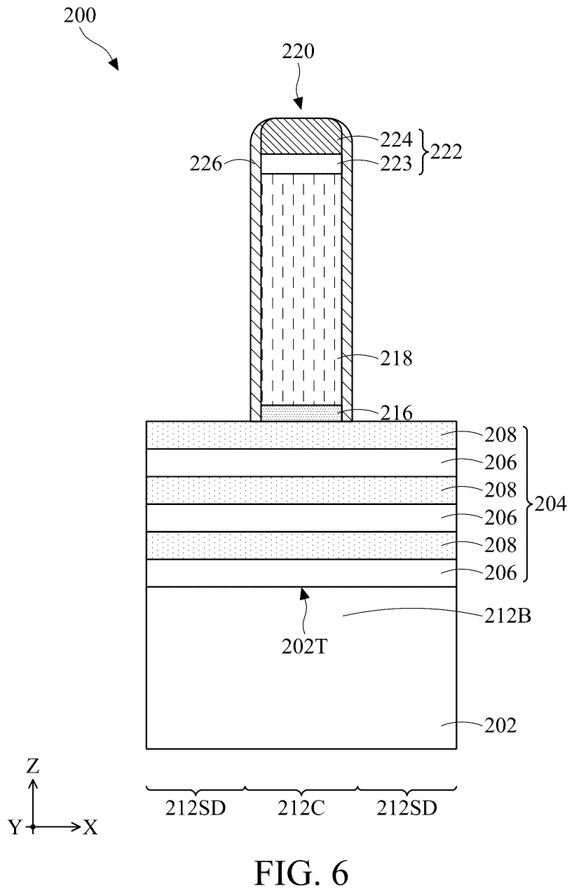

Referring to FIGS. 1 and 6, method 100 includes a block 108 where a gate spacer layer 226 is deposited over the dummy gate stack 220. In some embodiments, the gate spacer layer 226 is deposited conformally over the workpiece 200, including over top surface and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process. In one embodiment, the gate spacer layer 226 includes a first layer and a second layer disposed over the first layer. The first layer may include silicon oxynitride and the second layer may include silicon nitride. In some instances, the gate spacer layer 226 measures between about 3 nm and about 8 nm thick along the X direction.

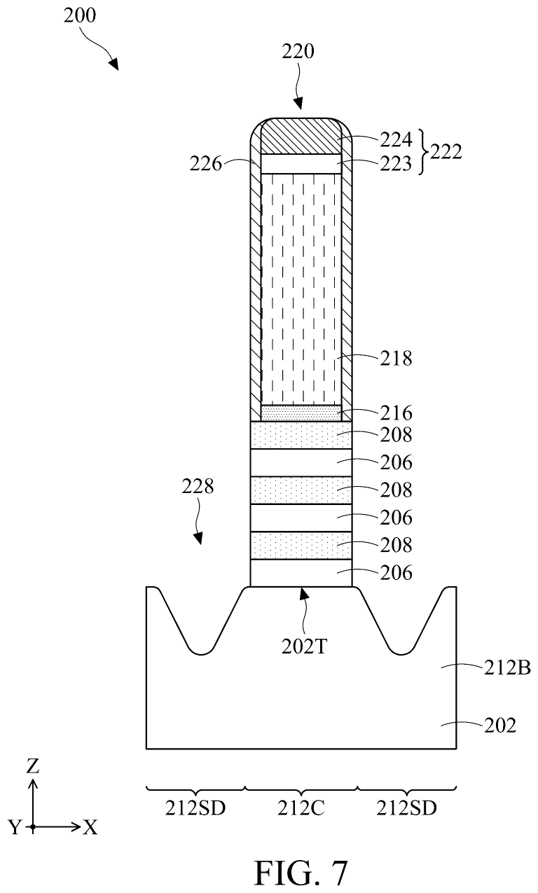

Referring to FIGS. 1 and 7, method 100 includes a block 110 where a source/drain region 212SD of the fin-shape structure 212 is recessed to form a source/drain trench 228. In some embodiments, the source/drain regions 212SD that are not covered by the dummy gate stack 220 and the gate spacer layer 226 are etched by a dry etch or a suitable etching process to form the source/drain trenches 228. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR3), an iodine-containing gas, other suitable gases and/or plasmas, and/or combinations thereof. In some embodiments represented in FIG. 7, the source/drain regions 212SD of the fin-shape structure 212 are recessed to expose sidewalls of the sacrificial layers 206 and the channel layers 208. In some implementations, the source/drain trenches 228 extend below the stack 204 into the substrate 202 (below the plane 202T). FIG. 7 illustrates a cross-sectional view of the workpiece 200 viewed along the Y direction at the source/drain region 212SD. As shown in FIG. 7, the sacrificial layers 206 and channel layers 208 in the source/drain region 212SD are removed at block 110, exposing the substrate 202.

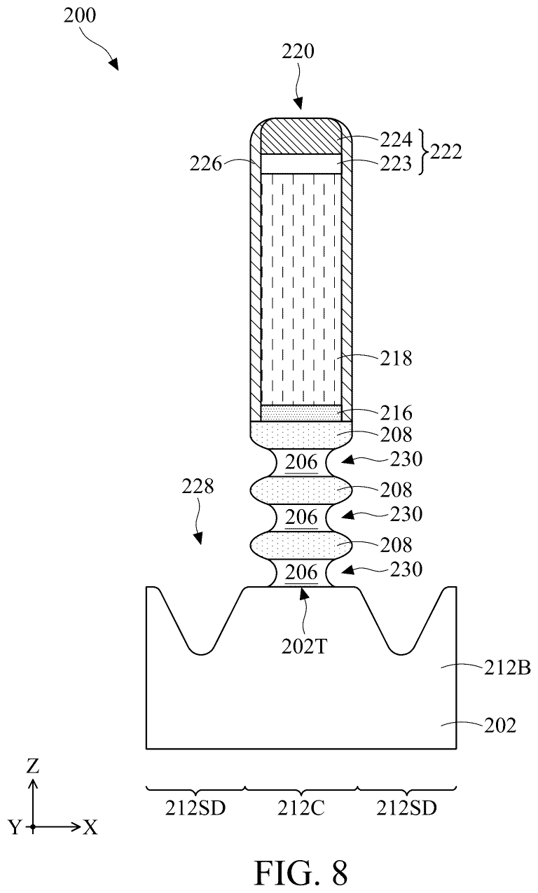

Referring to FIGS. 1, 8, 9, and 10, method 100 includes a block 112 where inner spacer features 234 are formed. While not shown explicitly, operation at block 112 may include selective and partial removal of the sacrificial layers 206 to form inner spacer recesses 230, deposition of inner spacer material 232 over the workpiece 200, and etch back the inner spacer material 232 to form inner spacer features 234 in the inner spacer recesses 230. The sacrificial layers 206 exposed in the source/drain trenches 228 (shown in FIG. 8) are selectively and partially recessed to form inner spacer recesses 230 while the gate spacer layer 226, the exposed portion of the substrate 202, and the channel layers 208 are substantially unetched. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. The selective and partial recess of the sacrificial layers 206 may include a SiGe oxidation process followed by a SiGe oxide removal. In that embodiment, the SiGe oxidation process may include use of ozone. In some other embodiments, the selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

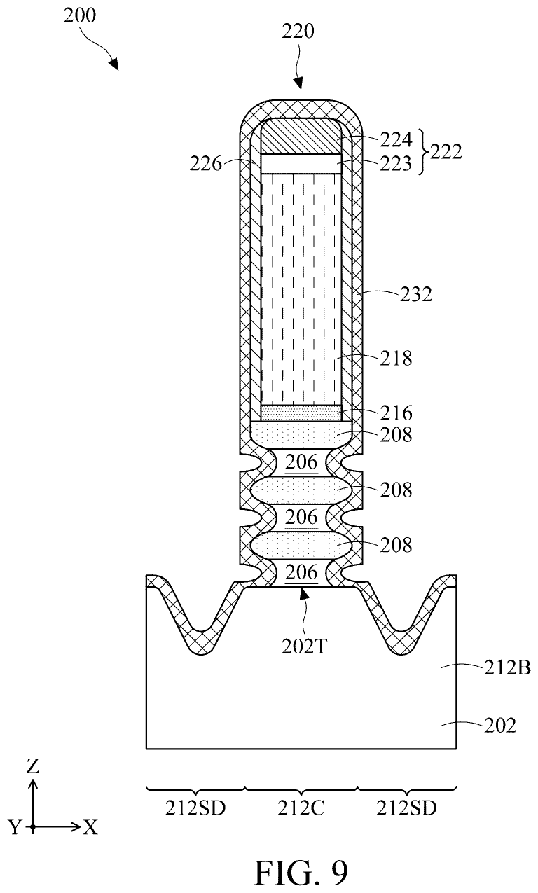

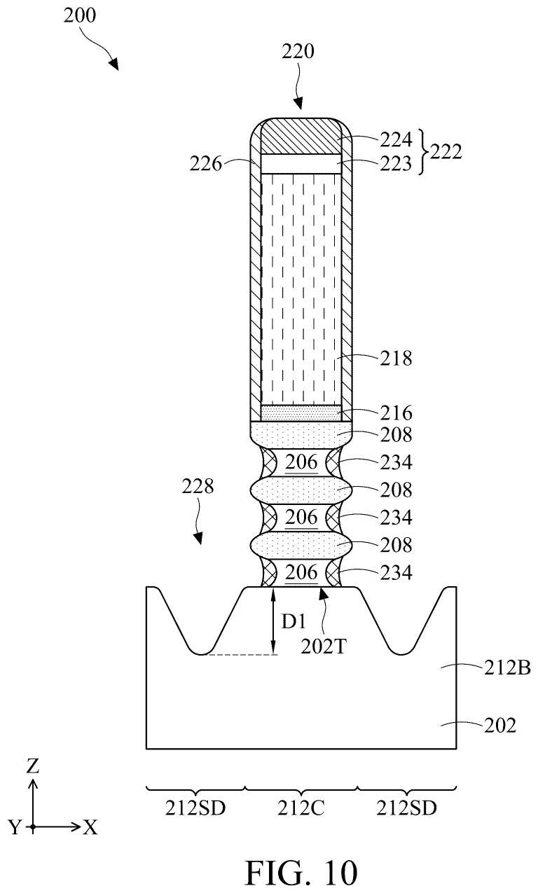

After the inner spacer recesses 230 are formed, the inner spacer material 232 is deposited over the workpiece 200, including over the inner spacer recesses 230, as shown in FIG. 9. The inner spacer material 232 may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material 232 may be a single layer or a multilayer. In some implementations, the inner spacer material 232 may be deposited using CVD, PECVD, SACVD, ALD or other suitable methods. The inner spacer material 232 is deposited into the inner spacer recesses 230 as well as over the sidewalls of the channel layers 208 exposed in the source/drain trenches 228. Referring to FIG. 10, the deposited inner spacer material 232 is then etched back to remove the inner spacer material 232 from the sidewalls of the channel layers 208 to form the inner spacer features 234 in the inner spacer recesses 230. At block 112, the inner spacer material 232 may also be removed from the top surfaces and/or sidewalls of the gate-top hard mask layer 222 and the gate spacer layer 226. In some implementations, the etch back operations performed at block 112 may include use of hydrogen fluoride (HF), fluorine gas (F₂), hydrogen (H₂), ammonia (NH₃), nitrogen trifluoride (NF₃), or other fluorine-based etchants. As shown in FIG. 10, each of the inner spacer features 234 is in direct contact with the recessed sacrificial layers 206 and is disposed between two neighboring channel layers 208. In some instances, each of the inner spacer features 234 measures between about 3 nm and about 5 nm thick along the X direction. In the depicted embodiment, each of the inner spacer features 234 has a concave sidewall surface facing the respective source/drain trench 228 (i.e.., bending inward towards the respective sacrificial layer 206). Alternatively, the sidewall surface may be flat (e.g., substantially vertical) or convex (i.e.., bending outward towards the respective source/drain trench 228). As shown in FIG. 10, while the selective etch process and etch back process at block 112 are selective to the sacrificial layers 206 and the inner spacer material 232, the channel layers 208 are moderately etched and have rounded ends. In the depicted embodiment, the source/drain trench 228 extends a depth D1 into the substrate 202 (measured from the plane 202T) and the depth D1 is between about 3 nm and about 115 nm. A width of the source/drain trench 228 (e.g., as measured between opposing sidewalls of the gate spacer layer 226 on adjacent dummy gate stacks 220 along the X direction) is between about 9 nm to about 32 nm.

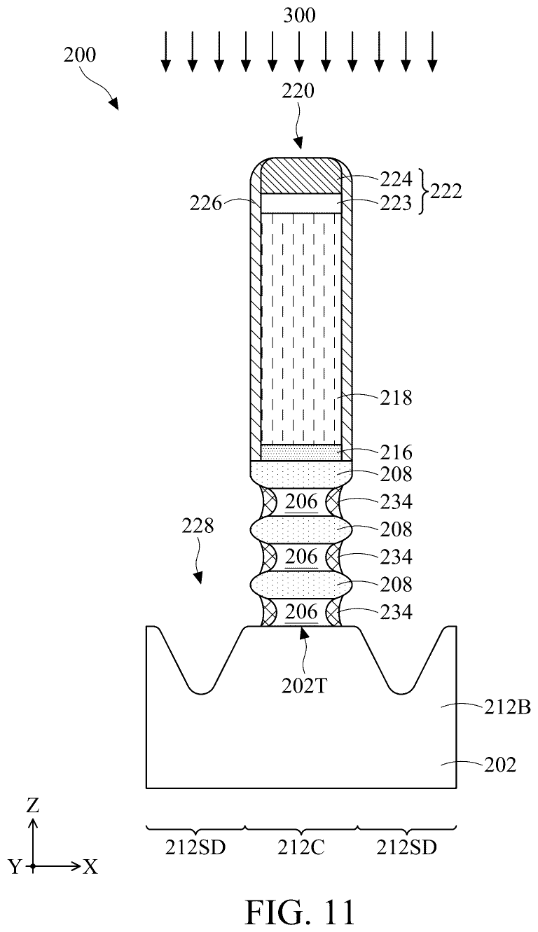

Referring to FIGS. 1 and 11, method 100 includes a block 114 where a cleaning process 300 is performed. The cleaning process 300 may include a dry clean, a wet clean, or a combination thereof. In some examples, the wet clean may use a suitable clean solution, such as a solution including a mixture of deionized (DI) water, ammonium hydroxide, and hydrogen peroxide, a solution including a mixture of DI water, hydrochloric acid, and hydrogen peroxide), SPM (a sulfuric peroxide mixture), and/or hydrofluoric acid for oxide removal. The dry clean process may include helium (He) and hydrogen (H₂) treatment at a temperature between about 250° C. and about 550° C. and under a pressure between about 75 mTorr and about 155 mTorr. The hydrogen treatment may convert silicon on the surface to silane (SiH₄), which may be pumped out for removal. In some implementations, the cleaning process is configured to selectively remove or trim a portion of the channel layers without substantially removing the inner spacer features 234. The cleaning process 300 may remove surface oxide and debris in order to ensure a clean semiconductor surface, which facilitates growth of a base epitaxial layer at block 116.

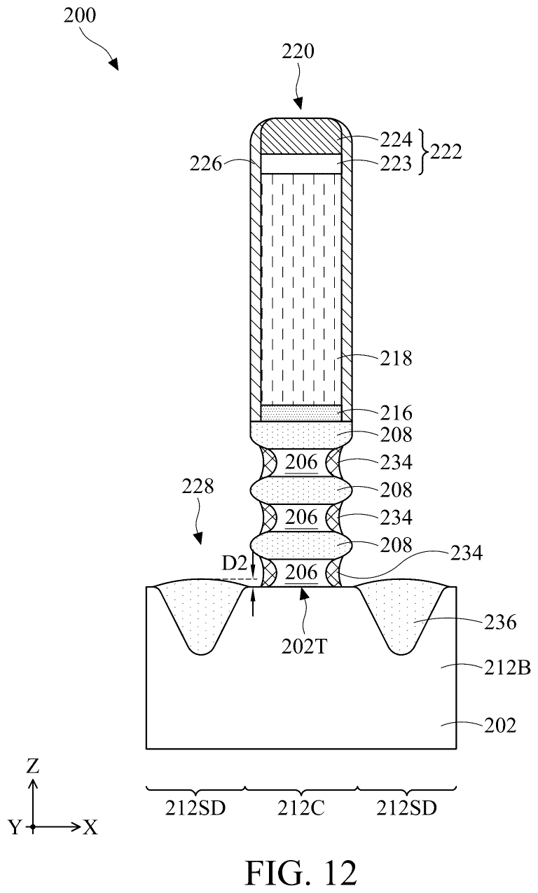

Referring to FIGS. 1 and 12, method 100 includes a block 116 where a base epitaxial layer 236 is deposited in the bottom of the source/drain trench 228. In some embodiments, the base epitaxial layer 236 includes the same material as the substrate 202 and the channel layers 208, such as silicon (Si), except for a dopant condition (doping element and/or doping concentration). For example, the base epitaxial layer 236 is made of non-doped silicon, the substrate 202 is made of doped silicon, and the channel layers 208 are made of non-doped or doped silicon. In some embodiments, the base epitaxial layer 236 includes the same material as the sacrificial layers 206, such as silicon germanium (SiGe), with the germanium (Ge) content the same of different from each other. In some embodiments, the base epitaxial layer 236 includes SiₓGe₁₋ₓ, in which x is between about 0.1 and 1. The germanium content range is not trivial. When the germanium content is greater than about 90%, the lattice mismatch between silicon and germanium may cause too much defect at the interface between the base epitaxial layer 236 and the substrate 202. In other embodiments, the base epitaxial layer 236, the channel layers 208, and the sacrificial layers 206 are made of semiconductor materials different from each other. In various embodiments, the base epitaxial layer 236 is dopant-free, where for example, no intentional doping is performed during the epitaxial growth process. As a comparison, in one instance, the substrate 202 is lightly doped (e.g., n-type dopants in p-type regions for forming PFETs or p-type dopant in n-type regions for forming NFETs) and thus has a higher doping concentration than the base epitaxial layer 236. The dopant-free base epitaxial layer 236 provides a high resistance path from the subsequently formed source/drain features to the substrate 202, such that the leakage current into the substrate 202 is suppressed.

Suitable epitaxial processes for block 116 include vapor-phase epitaxy (VPE), molecular beam epitaxy (MBE), selective CVD, and/or other suitable processes. Various deposition parameters can be tuned to selectively deposit the semiconductor material on exposed semiconductor surfaces in the source/drain trenches 228, such as deposition gas composition, carrier gas composition, deposition gas flow rate, carrier gas flow rate, deposition time, deposition pressure, deposition temperature, source power, RF bias voltage, DC bias voltage, RF bias power, DC bias power, other suitable deposition parameters, or combinations thereof. In some embodiments, the workpiece 200 is exposed to a deposition mixture that includes DCS and/or SiH₄ (silicon-containing precursor), H₂ (carrier precursor), and HCl (etchant-containing precursor) when forming the base epitaxial layer 236. In some embodiments, the selective CVD process implements a deposition temperature of about 600° C. to about 750° C. In some embodiments, the selective CVD process implements a deposition pressure of about 10 Torr to about 100 Torr. In some embodiments, the selective CVD process is configured as a bottom-up deposition process, such that base epitaxial layer 236 grows from the exposed semiconductor surface at the bottom of the source/drain trenches 228, but not from exposed end portions of the channel layers 208. In some embodiments, the growth of the base epitaxial layer 236 is under time control such that the top surface of the base epitaxial layer 236 is about the top surface of the fin-shape base 212B (i.e.., above the plane 202T). In some embodiments, the top surface of the base epitaxial layer 236 is above the plane 202T for a distance D2 that ranges between about 1 nm and about 5 nm. In some alternative embodiments, the top surface of the base epitaxial layer 236 is below the plane 202T for about 2 nm to about 20 nm.

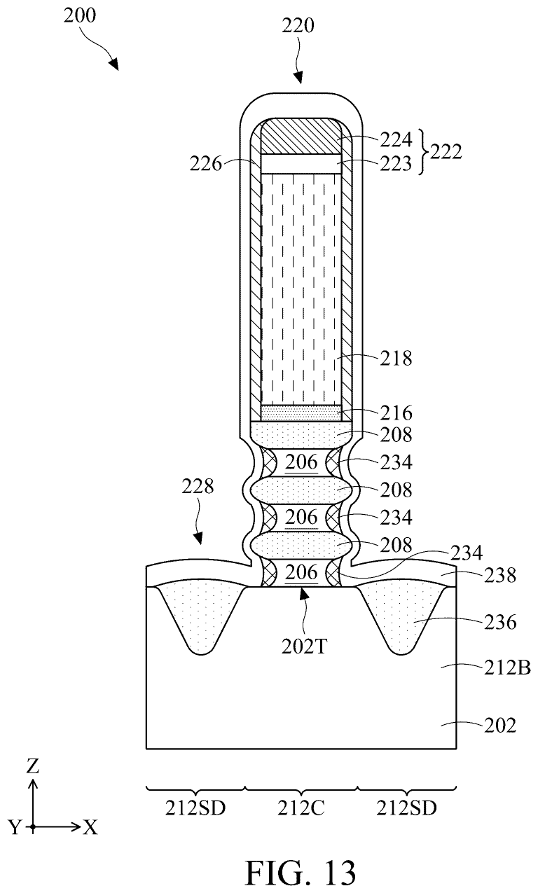

Referring to FIGS. 1, 13, and 14, method 100 includes a block 118 where a dielectric film 240 is formed in the bottom of the source/drain trenches 228 and above the base epitaxial layer 236. While not shown explicitly, operation at block 118 may include deposition of dielectric material 238 over the workpiece 200, and etch back the dielectric material 238 to form the dielectric film 240 in the bottom of the source/drain trenches 228. The dielectric material 238 is deposited over the workpiece 200, including over sidewalls and bottom surfaces of the source/drain trenches 228 and over sidewalls and top surfaces of the dummy gate stack 220, as shown in FIG. 13. In some embodiments, the dielectric material 238 may include a metal oxide or a metal nitride, such as La₂O₃, Al₂O₃, ZnO, ZrN, Zr₂Al₃O₉, TiO₂, TaO₂, ZrO₂, HfO₂, Y₂O₃, AlON, TaCN, other suitable material(s), or combinations thereof. In some embodiments, the dielectric material 238 may include silicon oxide, silicon oxycarbonitride, silicon nitride, silicon oxynitride, carbon-rich silicon carbonitride, or a low-k dielectric material. The dielectric material 238 is selected such that it has a different etch selectivity from the inner spacer features 234, allowing the etching back of the dielectric material 238 without causing etching loss to the inner spacer features 234. In some implementations, the dielectric material 238 may be deposited using a directional deposition process, such as PECVD or other suitable methods. The directional deposition process forms the dielectric material 238 with thicker horizontal portions (e.g., on the bottom surface of the source/drain trenches 228 and the top surface of the dummy gate stack 220) and thinner vertical portions (e.g., on the sidewalls of the dummy gate stack 220 and the fin-shape structure 212).

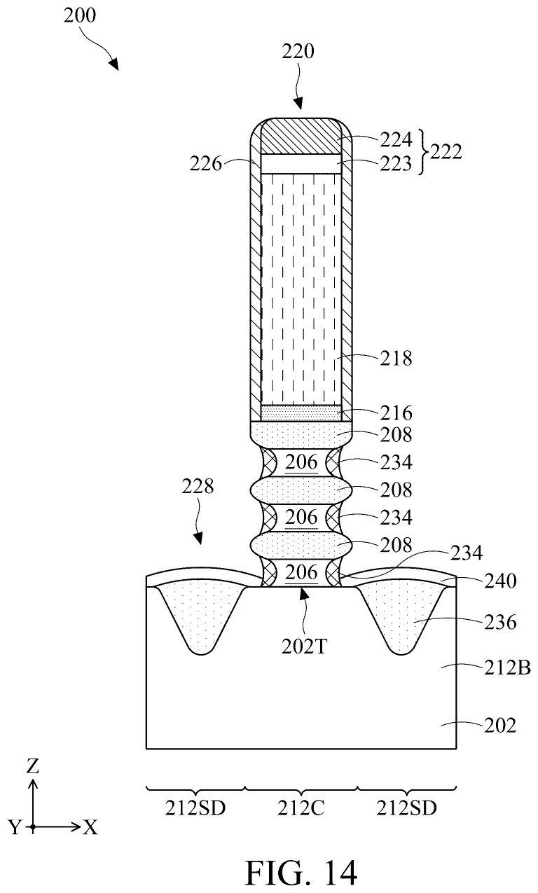

Referring to FIG. 14, the deposited dielectric material 238 is then etched back to remove the thinner vertical portions from the sidewalls of the dummy gate stack 220 and the fin-shape structure 212. In some implementations, the etch back operations performed at block 118 may include use of hydrogen fluoride (HF), fluorine gas (F₂), hydrogen (H₂), ammonia (NH₃), nitrogen trifluoride (NF₃), or other fluorine-based etchants. The thicker horizontal portion atop the dummy gate stack 220 may also be removed due to the loading effect, while the thicker horizontal portion in the bottom of the source/drain trenches 228 is thinned down but still remains as the dielectric film 240, which covers the base epitaxial layer 236. In some embodiments, the dielectric film 240 has a thickness (measured in Z direction) of about 2 nm to about 20 nm. In the depicted embodiment, the top surface of the dielectric film 240 is about the plane 202T, and the dielectric film 240 is in contact with the bottommost one of the inner spacers 234.

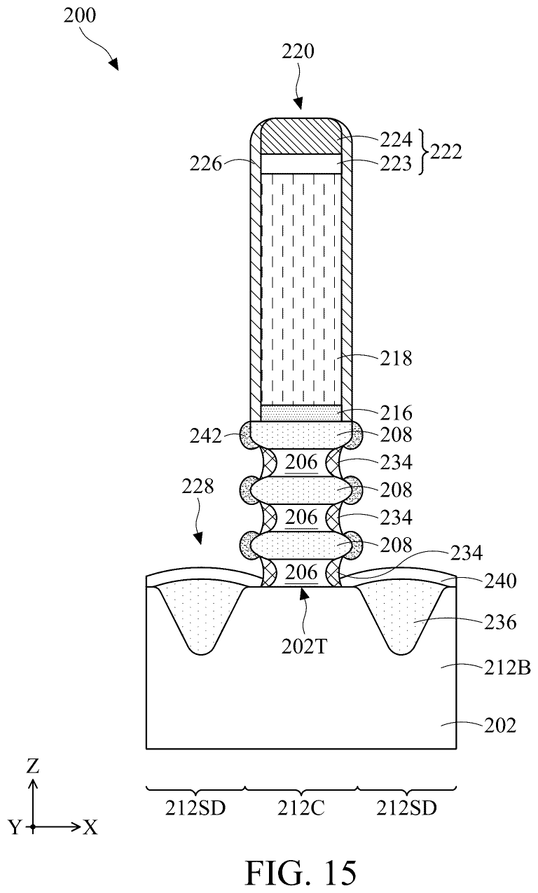

Referring to FIGS. 1 and 15, method 100 includes a block 120 where a first epitaxial layer 242 is deposited. The first epitaxial layer 242 may be epitaxially and selectively formed from the exposed sidewalls of the channel layers 208 while sidewalls of the sacrificial layers 206 remain covered by the inner spacer features 234. Suitable epitaxial processes for block 120 include vapor-phase epitaxy (VPE), ultra-high vacuum CVD (UHV-CVD), molecular beam epitaxy (MBE), and/or other suitable processes. The epitaxial growth process at block 120 may use gaseous precursors, which interact with the composition of the channel layers 208. In some embodiments, parameters of the epitaxial growth process at block 120 are selected such that the first epitaxial layer 242 is not epitaxially deposited on the inner spacer features 234. In some embodiments, upon conclusion of the operations at the block 120, at least some inner spacer features 234 remain exposed. That is, at least some inner spacer features 234 are not completely covered by the first epitaxial layer 242.

In some instances, in the p-type regions for forming p-type transistors, the first epitaxial layer 242 includes silicon germanium (SiGe) and is doped with a p-type dopant, such as boron (B). In some embodiments, the first epitaxial layer 242 includes a germanium (Ge) content between about 10% and about 40% and a silicon (Si) content between about 90% and about 60%. This germanium (Ge) content range is not trivial. When the germanium content is greater than about 40%, the lattice mismatch between silicon and germanium may cause too much defect at the interface between the first epitaxial layer 242 and the channel layers 208, which may lead to increased resistance or device failure. When the germanium content is smaller than about 10%, the channel layers 208 may not be sufficiently strained for improved hole mobility.

In some instances, in the n-type regions for forming n-type transistors, the first epitaxial layer 242 includes silicon arsenic (SiAs) and is doped with an n-type dopant, such as phosphorus (P). In some embodiments, the first epitaxial layer 242 includes an arsenic (As) content between about 10% and about 40% atomic percentage and a silicon (Si) content between about 90% and about 60% atomic percentage. This arsenic (As) content range is not trivial. When the arsenic content is greater than about 40%, the lattice mismatch between silicon and arsenic may cause too much defect at the interface between the first epitaxial layer 244A and the channel layers 208, which may lead to increased resistance or device failure. When the arsenic content is smaller than about 10%, the channel layers 208 may not be sufficiently strained for improved carrier mobility.

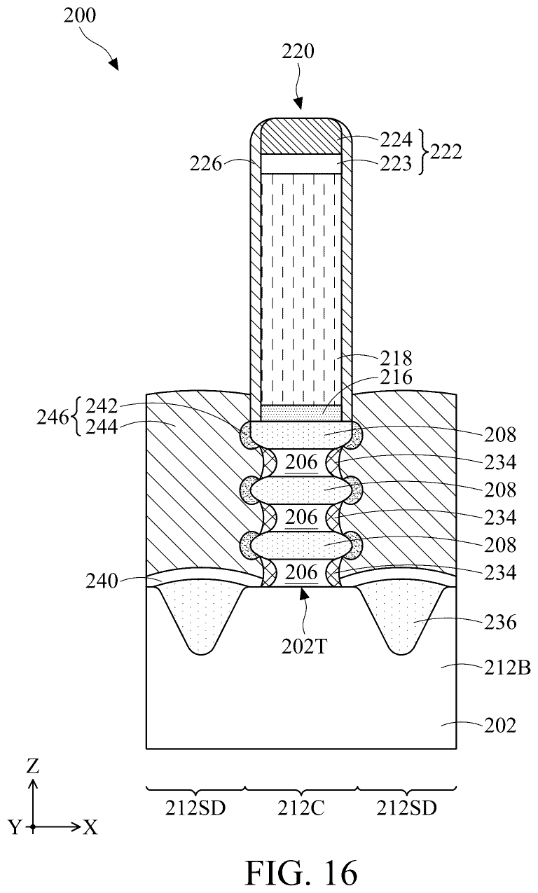

Referring to FIGS. 1 and 16, method 100 includes a block 122 where a second epitaxial layer 244 is deposited over the first epitaxial layer 242. The first epitaxial layer 242 and the second epitaxial layer 244 in a source/drain region 212SD are collectively referred to as a source/drain feature 246. In some embodiments, the second epitaxial layer 244 may be epitaxially and selectively formed from the first epitaxial layer 242. Suitable epitaxial processes for block 122 include vapor-phase epitaxy (VPE), ultra-high vacuum CVD (UHV-CVD), molecular beam epitaxy (MBE), and/or other suitable processes. The epitaxial growth process at block 122 may use gaseous precursors, which interact with the composition of the first epitaxial layer 242. The second epitaxial layer 244 is allowed to overgrow and merge over the inner spacer features 234 and substantially fill the source/drain trenches 228. A top surface of the second epitaxial layer 244 may grow above the top surface of the fin-shape structure 212 (i.e.., the top surface of the topmost channel layer 208) and intersect sidewalls of the gate spacer layer 226.

In some instances, in the p-type regions for forming p-type transistors, the second epitaxial layer 244 includes silicon germanium (SiGe) doped with a p-type dopant, such as boron (B). The second epitaxial layer 244 serves as a low resistance layer and includes a doping concentration greater than that in the first epitaxial layer 242. In some instances, the doping concentration in the second epitaxial layer 244 may be between about 1.2×10²⁰ atoms/cm³ and about 2×10²¹ atoms/cm³, and the doping concentration in the first epitaxial layer 242 may be between about 1×10¹⁸ atoms/cm³ and about 1×10²⁰ atoms/cm^{3.} The p-type dopant concentration ranges are not trivial. When the doping concentration of the p-type dopant in the second epitaxial layer 244 is lower than about 1.2×10²⁰ atoms/cm³, the resistance in the second epitaxial layer 244 may prevent satisfactory drive current (i.e., on-state current). When the dopant concentration of the p-type dopant in the second epitaxial layer 244 is greater than about 2×10²¹ atoms/cm³, p-type dopant in the lattice interstices may also cause too much defect, which may lead to increased resistance. The second epitaxial layer 244 may be in-situ doped for a substantially even distribution of the p-type dopant over depths. If the second epitaxial layer 244 is not in-situ doped, an ion implantation process is performed to dope the second epitaxial layer 244. The doping concentration in the second epitaxial layer 244 is capped by the solubility of boron (B) in the second epitaxial layer 244. Compared to the first epitaxial layer 242, the second epitaxial layer 244 includes a greater germanium content to enhance the strain on the channel layers 208. In some implementations, the second epitaxial layer 244 includes a germanium content between about 40% and about 70% and a silicon content between about 60% and about 30%. Compared to the second epitaxial layer 244, the base epitaxial layer 236 may include a greater germanium content. In an alternative embodiment, compared to the first epitaxial layer 242, the base epitaxial layer 236 may include a less germanium content.

In some instances, in the n-type regions for forming n-type transistors, the second epitaxial layer 244 includes silicon doped with an n-type dopant, such as phosphorus (P). The second epitaxial layer 244 serves as a low resistance layer and includes a doping concentration greater than that in the first epitaxial layer 242. Different from the p-type regions, the doping concentration in the second epitaxial layer 244 in the n-type regions is below the solubility of phosphorus in the second epitaxial layer 244. The second epitaxial layer 244 in the n-type regions may be in-situ doped for a substantially even distribution of the n-type dopant over depths. If the second epitaxial layer 244 is not in-situ doped, an ion implantation process may be performed to dope the second epitaxial layer 244. In some instances, the doping concentration in the second epitaxial layer 244 may be between about 2×10¹⁷ atoms/cm³ and about 5×10¹⁸ atoms/cm³, and the doping concentration in the first epitaxial layer 242 may be between about 1×10¹⁵ atoms/cm³ and about 1×10¹⁷ atoms/cm³, which is magnitudes lower than respective counterparts in the p-type regions. This is because a high concentration of phosphorus atoms accelerates diffusion of phosphorus atoms into the channel region along the boundary between the channel layers 208 and the inner spacer features 234 and arrive at the sacrificial layers 206. Since phosphorus atoms reduces etching contrast between the channel layers 208 and the sacrificial layers 206, during a gate replacement process in removing the sacrificial layers 206, the portion of the channel layers 208 diffused with phosphorus atoms may suffer excessive etching loss to the extent that a tunnel along the boundary between the channel layers 208 and the inner spacer features 234 may be formed. When a metal gate is formed during the gate replacement process, metal materials from the metal gate may extend into the tunnel and cause a short between the metal gate and the source/drain features, a phenomenon termed as “metal gate extrusion.” By keeping a relatively low phosphorus concentration in the n-type regions, metal gate extrusion can be prevented. In one embodiment, upon conclusion of the operations at the block 122, which is unlike in the p-type regions where the p-type dopant has been at a proper concentration, the source/drain features 246 in the n-type regions may even remain substantially un-doped or at a rather low concentration level. As discussed in further details below, an ion implantation process will be further performed in the n-type regions to boost the concentration of phosphorus in the source/drain features 246, after the gate replacement process.

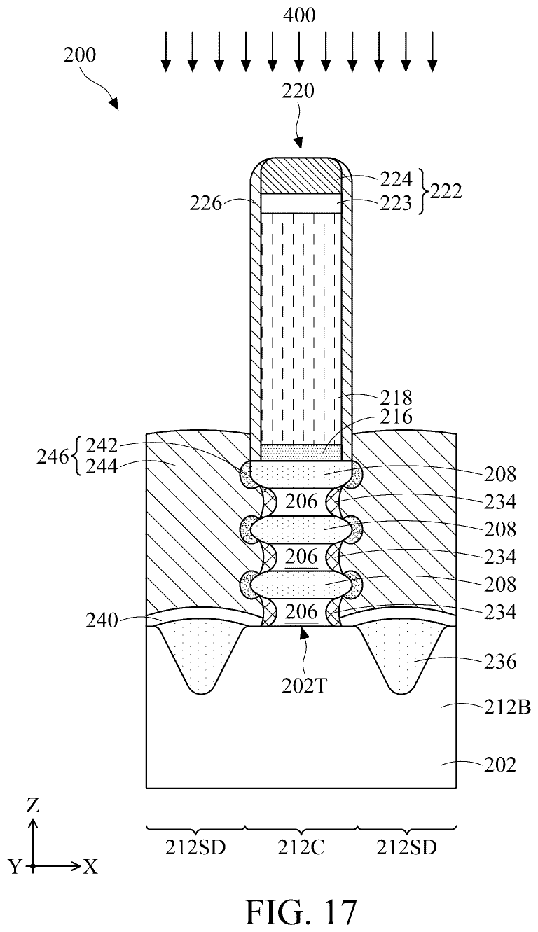

Referring to FIGS. 1 and 17, method 100 includes a block 124 where the workpiece 200 is annealed in an anneal process 400. In some implementation, the anneal process 400 may include a rapid thermal anneal (RTA) process, a laser spike anneal process, a flash anneal process, or a furnace anneal process. The anneal process 400 may include a peak anneal temperature between about 900° C. and about 1000° C. In these implementations, the peak anneal temperature may be maintained for a duration measured by seconds or microseconds. Through the anneal process 400, a desired electronic contribution of the p-type dopant in the semiconductor host, such as silicon germanium (SiGe) or germanium (Ge), may be obtained. The anneal process 400 may generate vacancies that facilitate movement of the p-type dopant from interstitial sites to substitutional lattice sites and reduce damages or defects in the lattice of the semiconductor host. Through the anneal process 400, the n-type dopant in the n-type regions, although with a rather low concentration level, is also more evenly distributed, particularly extending to the bottom portion of the source/drain features 246.

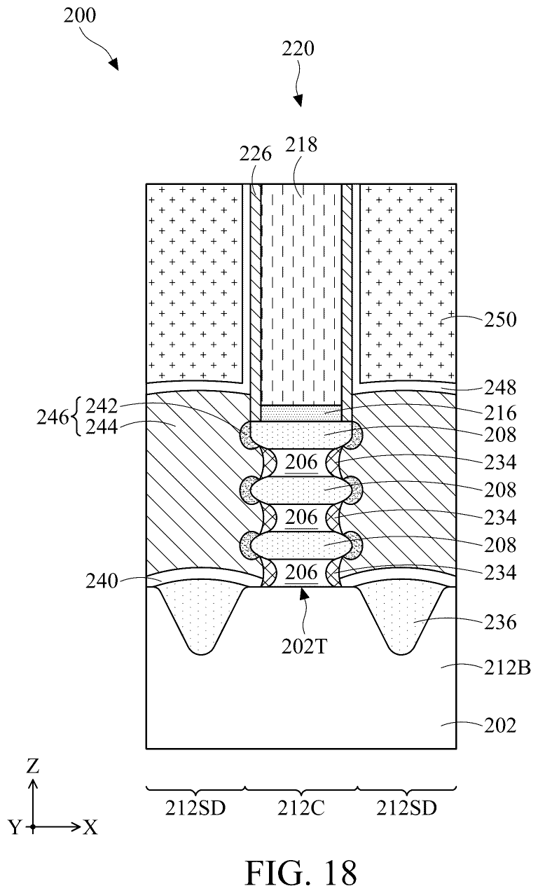

Referring to FIGS. 1 and 18, method 100 includes a block 126 where a contact etch stop layer (CESL) 248 and a first interlayer dielectric (ILD) layer 250 are deposited on the workpiece 200. In some embodiments, the CESL 248 includes silicon nitride, silicon oxynitride, and/or other materials known in the art. The CESL 248 may be formed by ALD, plasma-enhanced chemical vapor deposition (PECVD) process and/or other suitable deposition processes. The first ILD layer 250 is then deposited over the CESL 248. In some embodiments, the first ILD layer 250 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The first ILD layer 250 may be deposited by a PECVD process or other suitable deposition technique. In some embodiments, after formation of the first ILD layer 250, the workpiece 200 may be annealed to improve integrity of the first ILD layer 250. As shown in FIG. 18, the CESL 248 is disposed directly on top surfaces of the source/drain feature 246. After the deposition of the CESL 248 and the first ILD layer 250, the workpiece 200 may be planarized by a planarization process to expose the dummy gate stack 220. For example, the planarization process may include a chemical mechanical planarization (CMP) process. Exposure of the dummy gate stack 220 allows the removal of the dummy gate stack 220 and release of the channel layers 208.

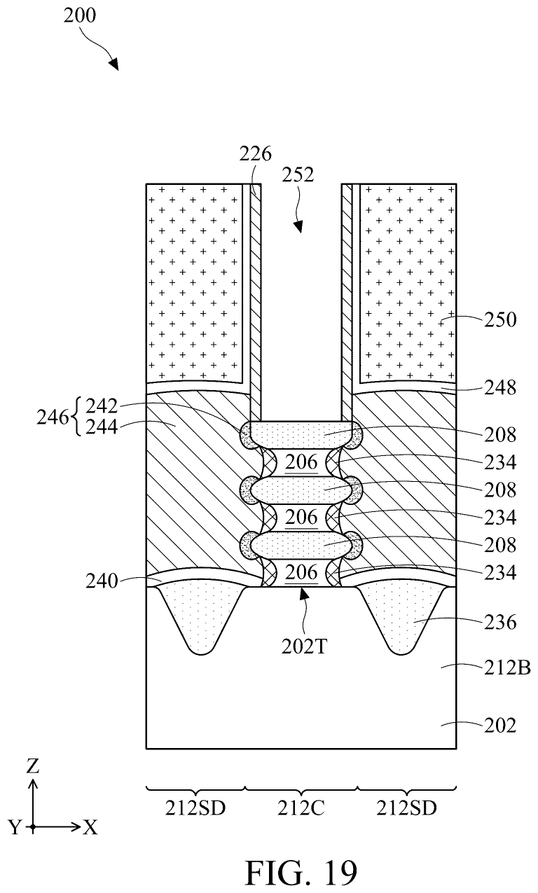

Referring to FIGS. 1 and 19, method 100 includes a block 128 where the dummy gate stack 220 is removed, resulting in a gate trench 252 over the channel regions 212C. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed in the gate trench 252.

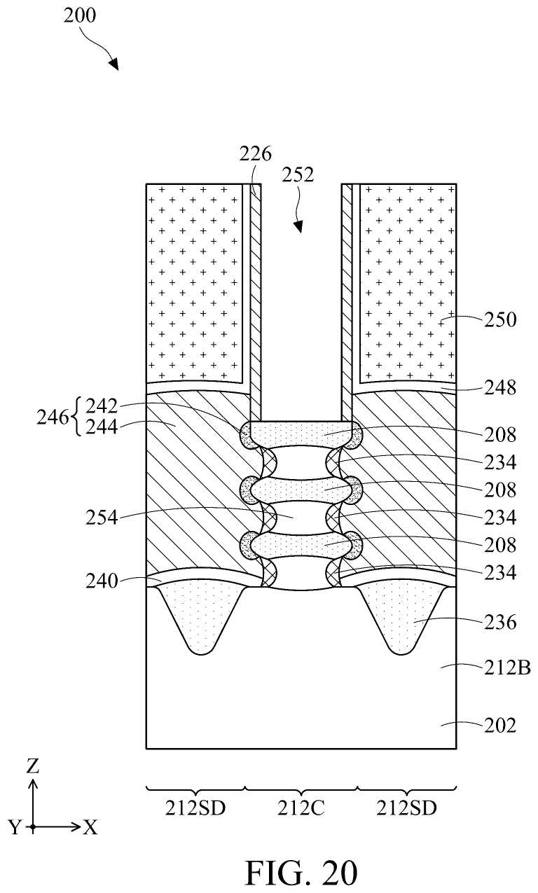

Referring to FIGS. 1 and 20, method 100 includes a block 130 where the sacrificial layers 206 between the channel layers 208 in the channel region 212C is selectively removed. The selective removal of the sacrificial layers 206 releases the channel layers 208 to form channel members (also numbered as 208). The selective removal of the sacrificial layers 206 also leaves behind space 254 between channel members 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

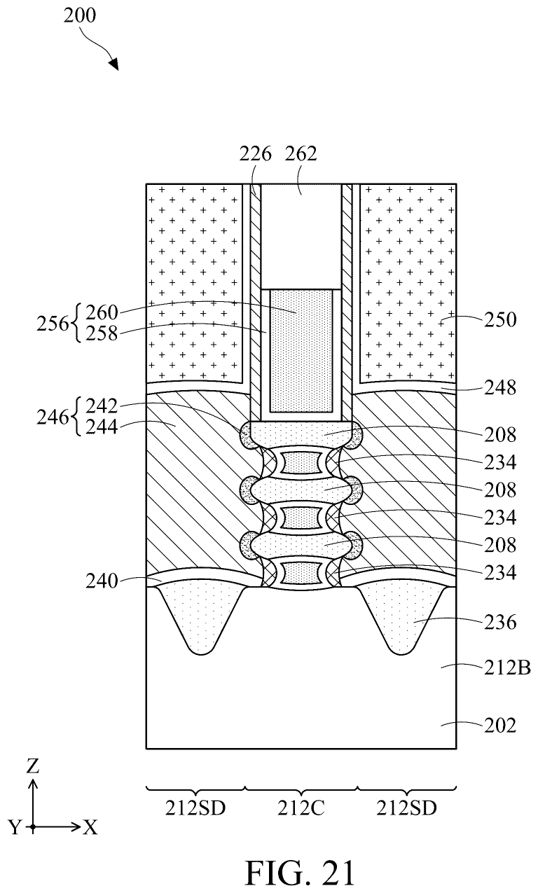

Referring to FIGS. 1 and 21, method 100 includes a block 132 where a gate structure 256 is formed to wrap around each of the channel members 208. In some embodiments, the gate structure 256 is formed within the gate trench 252 and into the space 254 left behind by the removal of the sacrificial layers 206. In this regard, the gate structure 256 wraps around each of the channel members 208. The gate structure 256 includes a gate dielectric layer 258 and a gate electrode layer 260 over the gate dielectric layer 258. In some embodiments, while not explicitly shown in the figures, the gate dielectric layer 258 includes an interfacial layer and a high-K gate dielectric layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxidc. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer 260 of the gate structure 256 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 260 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 260 may be formed by ALD, PVD, CVD, e-beam evaporation, or other suitable process. In various embodiments, a CMP process may be performed to remove excess metal, thereby providing a substantially planar top surface of the gate structure 256. The gate structure 256 includes portions that interpose between channel members 208 in the channel region 212C.

Still referring to FIG. 21, in the depicted embodiment, the gate structure 256 (including the gate dielectric layers 258 and the gate electrode layer 260) is recessed, so that a recess is formed directly over the gate structure 256 and between opposing portions of gate spacer layer 226. A gate mask 262 comprising one or more layers of dielectric material, such as silicon nitride, silicon oxynitride, or the like, is filled in the recess, followed by a planarization process to remove excess portions of the dielectric material extending over the first ILD layer 250. Subsequently formed gate contacts (not shown) penetrate through the gate mask 262 to contact the top surface of the recessed gate electrode layer 260. After the gate structure 256 is recessed, a distance from the top surface of the gate structure 256 to the top surface of the topmost channel member 208 may measure between about 5 nm and about 50 nm along the Z direction.

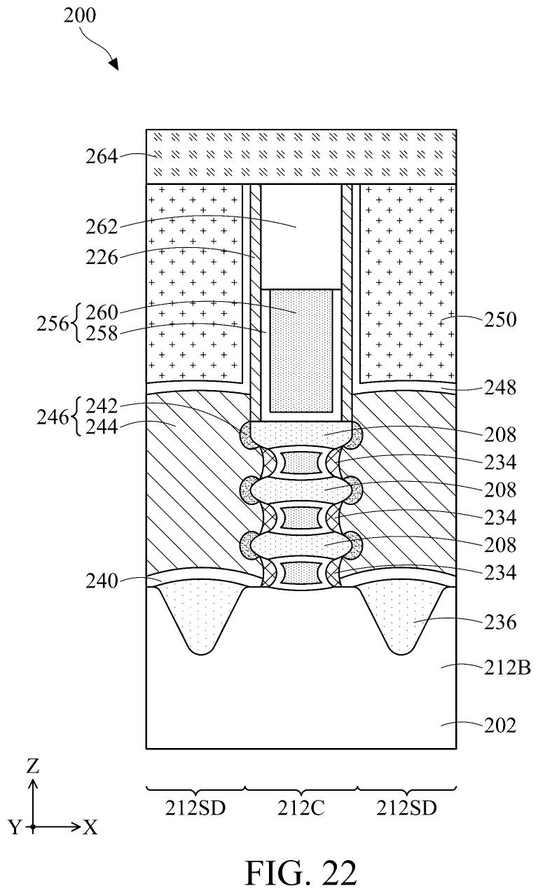

Referring to FIGS. 1 and 22, method 100 includes a block 134 where a second ILD layer 264 is deposited on the workpiece 200. The second ILD layer 264 may be a single layer or a multi-layer. In some embodiments, the second ILD layer 264 is a flowable film formed by a flowable CVD method. In some embodiments, the second ILD layer 264 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The second ILD layer 264 may be deposited by a PECVD process or other suitable deposition technique.

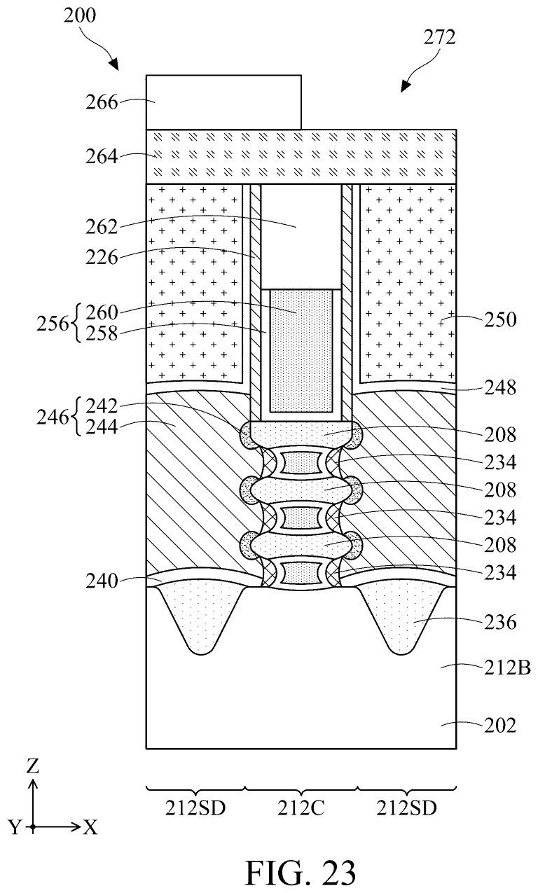

Referring to FIGS. 1 and 23, method 100 includes a block 136 where a hard mask layer 266 is formed on the second ILD layer 264. The hard mask layer 266 may include SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or other suitable materials. A thickness of the hard mask layer 266 may range from about 5 nm to about 30 nm. A lithography patterning and etching process is performed to pattern the hard mask layers 266. Particularly, the lithography process forms a patterned photoresist layer with an opening, and an etching process is applied to transfer the opening to the hard mask layer 266 as the opening 272. The opening 272 is larger than a size of the source/drain feature 246 underneath, such that a portion of the gate structure 256 is also overlayed directly under the opening 272.

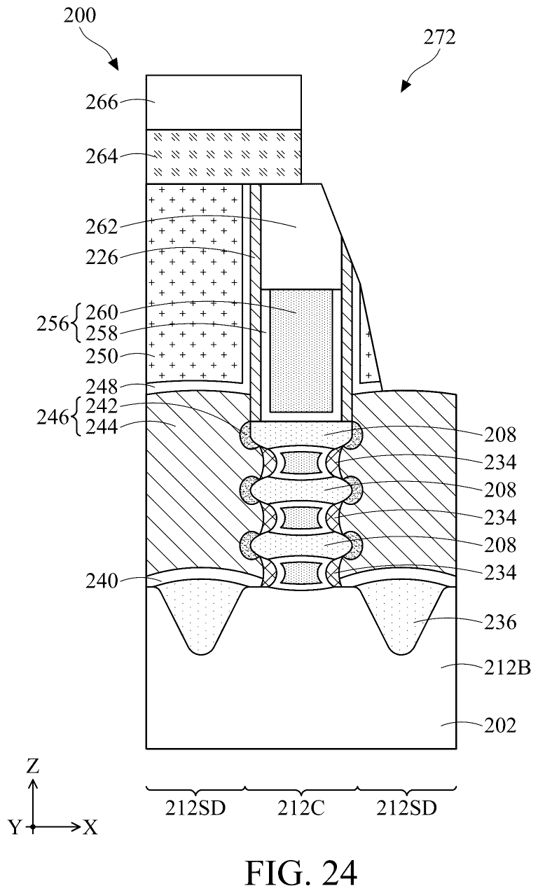

Referring to FIGS. 1 and 24, method 100 includes a block 138 where a selective etching process is performed to extend the opening 272 through the second ILD layer 264 and the first ILD layer 250 to expose the underneath source/drain feature 246. The opening 272 is also referred to as the source/drain contact hole 272 upon conclusion of the operations at the block 138. The selective etching process may include a dry etch (e.g., reactive ion etching), a wet etch, and/or other suitable process. In some embodiments, the etching process includes a first selective etching tuned to be selective to the materials in the second ILD layer 264 and the first ILD layer 250 with no (or minimal) etching to the CESL 248, the gate spacer layer 226, and the gate mask 262, and a second selective etching tuned to open the CESL 248 with no (or minimal) etching to the source/drain feature 246.

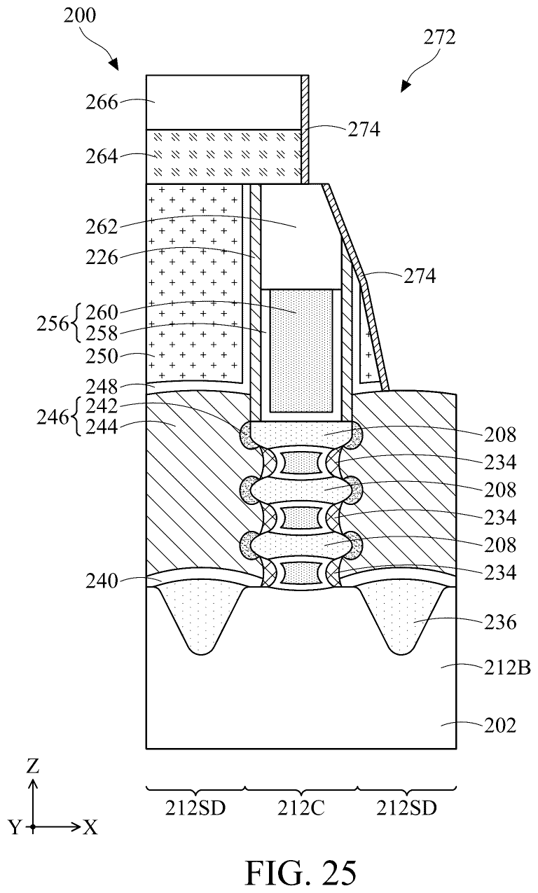

Referring to FIGS. 1 and 25, method 100 includes a block 140 where a liner 274 is deposited along sidewalls of the opening 272. The liner 274 functions to protect the gate structure 256 from dopant diffusion in a subsequent ion implantation process. The liner 274 may be a single layer or a multi-layer. In an example process, at least one metal material is conformally deposited over the workpiece 200 and then anisotropically etched back to expose the source/drain feature 246. In one instance, the liner 284 is a titanium (Ti) layer. In another example process, at least one dielectric material is deposited over the workpiece 200 and then the deposited dielectric material is anisotropically etched back to expose the source/drain feature 246. In some instances, the at least one dielectric material for the liner 284 may include silicon, oxygen, nitrogen, or carbon. For example, the at least one dielectric material may include silicon nitride, silicon carbonitride, silicon oxycarbonitride, silicon oxycarbide, or silicon oxynitride. After the etch back process, the liner 284 may have a thickness between about 1 nm and about 15 nm in the X direction.

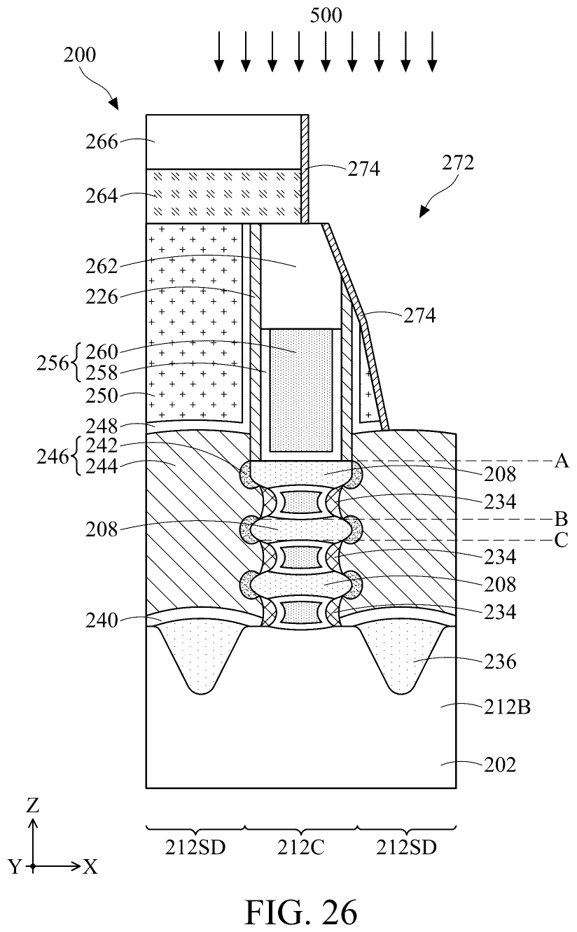

Referring to FIGS. 1 and 26, method 100 includes a block 142 where a phosphorus ion implantation 500 is performed in the n-type regions while the p-type regions are covered. The phosphorus ion implantation 500 provides relatively heavy and shallow doping on a top portion of the source/drain feature 246. The liner 284 may also be doped with phosphorus, which can be examined by a SIMS (Secondary Ion Mass Spectroscopy). In some embodiments, the phosphorus dimer (P₂+) ion is utilized at block 142 to effectively introduce a higher chemical phosphorus concentration and to increase a higher amorphous level. As a comparison, the conventional phosphorus ion implantation using P+ may be used at block 122 during the forming of the source/drain features 246. The phosphorus dimer ion implantation may include cooling the workpiece 200 to a temperature from a room temperature to a temperature of −20° C. in some embodiments, or below −20° C. in some other embodiments. The phosphorus dimer ion implantation at these cold temperatures induces more activated phosphorus dopants on the surface due to the relatively high amorphous degree (or lower activation energy needed for activation). As a result, the phosphorus dimer ion implantation performed as a cryo-implantation can cause more lateral straggle to occur compared to room-temperature implantation. This is because the colder temperatures cause the implanted phosphorus atoms to move further laterally relative to the point of initial penetration of the top surface of the strain material. Due to the lateral straggle, the phosphorus concentration at the same depth may be substantially the same, even between the first epitaxial layer 242 and the second epitaxial layer 244.

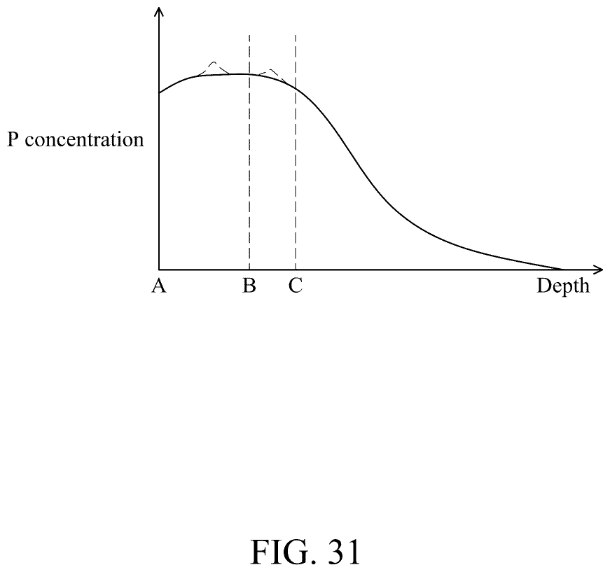

In some aspects, the phosphorus ion implantation 500 implants the dopant species using implant energy in a range from about 0.1 KeV to about 10 KeV. In some embodiments, the implant dosage is in a range from about 1×10¹⁵ atoms/cm³ to about 5×10¹⁵ atoms/cm³. In certain embodiments, phosphorus ion implantation 500 includes a first ion implantation with an implant energy in a range from about 2 KeV to about 3 Kev with a dosage in a range from about 1×10¹⁵ atoms/cm³ to about 5×10¹⁵ atoms/cm³, followed by a second ion implantation with an implant energy in a range from about 3 KeV to about 4 KeV with a dosage in a range from about 1×10¹⁵ atoms/cm³ to about 5×10¹⁵ atoms/cm³. Phosphorus atoms in the first ion implantation are mainly driven into a region between a top surface of the first top (topmost) channel member 208 to a top surface of the second top channel member 208 (between A and B lines in FIG. 26). Phosphorus atoms in the second ion implantation are mainly driven into a region between a top surface of the second top channel member 208 to a bottom surface of the second top channel member 208 (between B and C lines in FIG. 26). To fine tune the doping to fit different device performance requirements, the first ion implantation may be performed prior to or after the second ion implantation. FIG. 31 illustrates a plot of an example of a phosphorus concentration profile over a range of depths. As shown in FIG. 31, the peak phosphorus concentration is in the region between A-C region, particularly between A-B region in a few nm above the B line, which may be greater than about 1×10²² atoms/cm³. In contrast, phosphorus concentration in the region below C line is magnitudes smaller than the peak. In some embodiments, the plot may have two peaks (represented by dotted lines in FIG. 31), with a first peak in the A-B region corresponding to the first ion implantation, and a second peak in the B-C region corresponding to the second ion implantation. The first peak may be higher than the second peak.

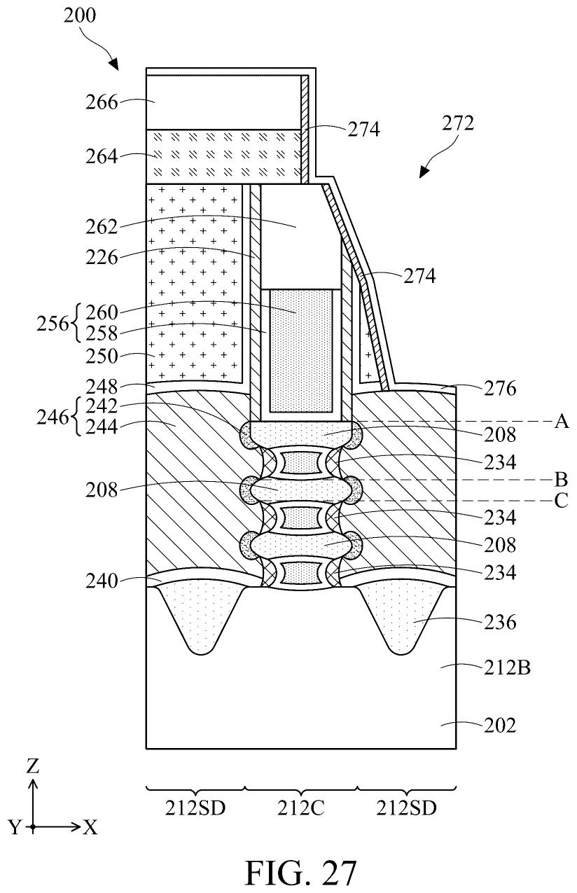

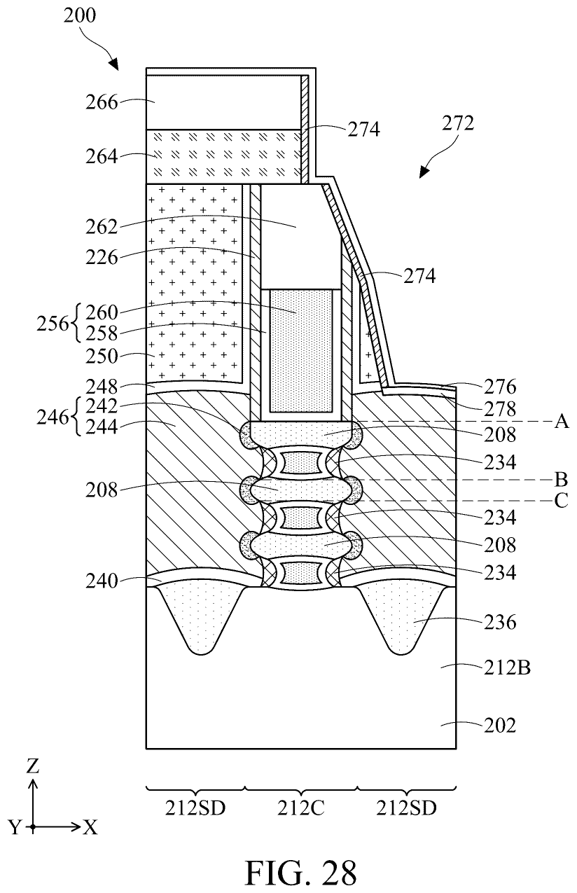

Referring to FIGS. 1, 27, and 28, method 100 includes a block 144 where a silicide layer 278 is formed on the source/drain region 212SD. In forming the silicide layer 278, a metal layer 276 may be first conformally deposited on the exposed surfaces of the workpiece 200, including exposed portion of the gate mask 262, the liner 274, and the top surface of the source/drain feature 246, as shown in FIG. 27. In some embodiments, the metal layer 276 is a titanium nitride (TiN) layer. The metal layer 276 may have a thickness between about 1 nm and about 5 nm in the X direction. After the metal layer 276 is deposited, the silicide layer 278 may be formed by reacting an upper portion of the source/drain feature 246 with the metal layer 276, as shown in FIG. 28. In some embodiments, the workpiece 200 is subjected to an anneal process, such as a rapid thermal anneal (RTA), to cause the silicide reaction to occur where the metal layer 276 and the liner 274 are in contact with the source/drain features 246. The bottom portions of the liner 274 and the metal layer 276 are converted to the silicide layer 278 containing TiSi. A top portion of the metal layer 276 may remain on the top surface of silicide layer 278 as a barrier layer to prevent oxidation of the silicide layer 278. Thus, the remaining horizontal portion of the metal layer 276 may be thinner than the vertical portion of the metal layer 276.

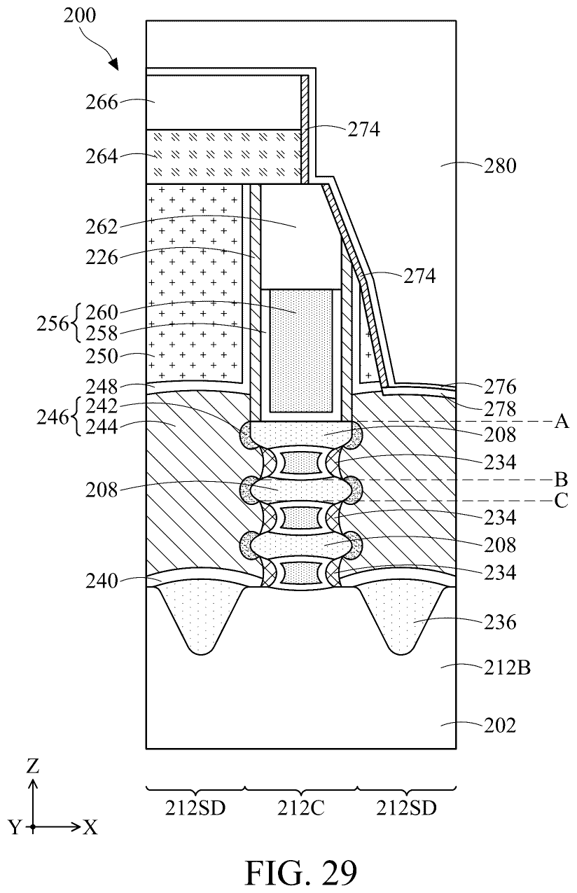

Referring to FIGS. 1, 29, and 30, method 100 includes a block 146 where a source/drain contact 282 is formed in the opening 272. In forming the source/drain contact 282, a conductive material 280 may be deposited in the opening 272, as shown in FIG. 29. The conductive material 280 may include cobalt, tungsten, copper, ruthenium, aluminum, gold, silver, alloys thereof, the like, or a combination thereof, and may be deposited by CVD, ALD, PVD, ECP or any suitable deposition technique. After the conductive material 280 is deposited, excess conductive material 280 may be removed by using a planarization process, such as a CMP, for example. The planarization process may remove excess conductive material 280 from above a top surface of the first ILD layer 250 with the remaining portion of the conductive material 280 as the source/drain contact 282. Hence, top surfaces of the source/drain contact 282, the first ILD layer 250, and the gate mask 262 may be coplanar.

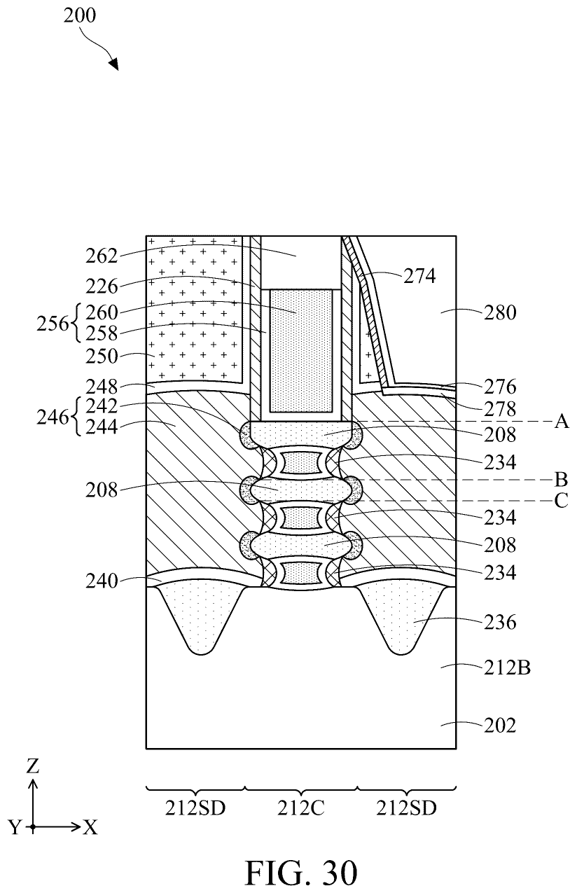

Still referring to FIG. 30, upon conclusion of the operations at the block 146, a transistor 290, particularly an n-type transistor 290, is substantially formed. The n-type transistor 290 may find applications in various circuits, such as being paired with a p-type transistor in an inverter of a static random-access memory (SRAM) cell. An SRAM cell incorporating the n-type transistor 290 may benefit a 3% higher cell current and 20 mV lower minimum operating voltage due to the lower-resistance and higher strain in the source/drain regions. The transistor 290 includes channel members 208 that are vertically stacked along the Z direction. Each of the channel members 208 is wrapped around by the gate structure 256. The channel members 208 extend or are sandwiched between two source/drain features 246 along the X direction. Each of the source/drain features 246 includes the first epitaxial layer 242 in contact with the channel members 208, and the second epitaxial layer 244 in contact with the first epitaxial layer 242. The second epitaxial layer 244 is spaced apart from the channel members 208 by the first epitaxial layers 242. Underneath the source/drain features 246 are the dielectric film 240 and the base epitaxial layer 236. Compared to the p-type transistors, which may have a substantially even distribution of a p-type dopant in the source/drain features over depths, the n-type transistor 280 has an uneven distribution of an n-type dopant over depths. For example, a top portion of the source/drain feature 246, which may be above the bottom surface of the top ones of the channel members 208 (e.g., top two channel members 208 or above the C line in FIG. 30), has a high phosphorus concentration; while as a contrast, a bottom portion of the source/drain feature 246 has a phosphorus concentration that is magnitudes lower. The phosphorus concentration in the n-type transistor 290 may be even higher than the p-type dopant in the p-type transistors due to the extra phosphorus ion implantation performed after the gate replacement process. Since the gate structure 256 is formed prior to the extra doping of phosphorus, metal gate extrusion is prevented.

In one exemplary aspect, the present disclosure is directed to a method. The method includes forming a stack over a substrate, the stack including a plurality of channel layers interleaved by a plurality of sacrificial layers, patterning the stack to form a fin-shape structure, the fin-shape structure including a channel region and a source/drain region, forming a dummy gate stack over the channel region of the fin-shape structure, depositing gate spacers on sidewalls of the dummy gate stack, recessing the source/drain region to form a source/drain trench that exposes sidewalls of the channel layers and the sacrificial layers, partially recessing the sacrificial layers to form a plurality of inner spacer recesses, forming a plurality of inner spacers in the inner spacer recesses, forming an epitaxial feature in the source/drain trench, after the forming of the epitaxial feature, removing the dummy gate stack, releasing the channel layers in the channel region as a plurality of channel members, forming a gate structure wrapping around each of the channel members, and after the forming of the gate structure, performing an ion implantation to increase a dopant concentration of a dopant in the epitaxial feature. In some embodiments, the dopant is an n-type dopant. In some embodiments, the dopant is phosphorus. In some embodiments, the method also includes depositing a dielectric layer over the epitaxial feature, etching through the dielectric layer to form a hole exposing a top surface of the epitaxial feature, and prior to the performing of the ion implantation, depositing a liner along sidewalls of the hole. In some embodiments, the liner is a titanium layer. In some embodiments, the ion implantation uses phosphorus dimer. In some embodiments, the dopant concentration has a first peak located above a top surface of a top second one of the channel members. In some embodiments, the dopant concentration has a second peak located between the top surface and a bottom surface of the top second one of the channel members. In some embodiments, the dopant concentration in a bottom portion of the epitaxial feature is at least one magnitude lower than in a top portion of the epitaxial feature. In some embodiments, the dopant concentration at a same depth of the epitaxial feature is substantially same.

In another exemplary aspect, the present disclosure is directed to a method. The method includes forming a plurality of channel members disposed over a fin-shape substrate, forming a plurality of inner spacers interleaving the channel members, forming an epitaxial feature abutting the channel members, forming a gate structure wrapping around each of the channel members, and after the forming of the gate structure, increasing a dopant concentration in the epitaxial feature. In some embodiments, the increasing of the dopant concentration includes a phosphorus ion implantation process. In some embodiments, the dopant concentration has a peak above about 1×10²² atoms/cm³. In some embodiments, the peak is located above a bottom surface of a top second one of the channel members. In some embodiments, the dopant concentration has another peak in a depth lower than where the peak locates. In some embodiments, prior to the increasing of the dopant concentration, the epitaxial feature is substantially undoped. In some embodiments, the epitaxial feature includes a first epitaxial layer abutting the channel members and a second epitaxial layer abutting the inner spacers, wherein the first and second epitaxial layers located at a same depth of the epitaxial feature have a substantially same dopant concentration.

In yet another exemplary aspect, the present disclosure is directed to a semiconductor device. The semiconductor device includes a plurality of channel members disposed over a substrate, a plurality of inner spacers interleaving the channel members, a gate structure wrapping around each of the channel members, a gate spacer layer disposed on sidewalls of the gate structure, and a source/drain feature abutting the channel members. The source/drain feature has a dopant concentration profile that has a peak located above a top surface of a second one of the channel members from top. In some embodiments, the peak is above about 1×10²² atoms/cm³. In some embodiments, the semiconductor device also includes a liner disposed on sidewalls of the gate spacer layer. The liner includes the same dopant as in the source/drain feature.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack over a substrate, the stack comprising a plurality of channel layers interleaved by a plurality of sacrificial layers;
patterning the stack to form a fin-shape structure, the fin-shape structure comprising a channel region and a source/drain region;
forming a dummy gate stack over the channel region of the fin-shape structure;
depositing gate spacers on sidewalls of the dummy gate stack;
recessing the source/drain region to form a source/drain trench that exposes sidewalls of the channel layers and the sacrificial layers;
partially recessing the sacrificial layers to form a plurality of inner spacer recesses;
forming a plurality of inner spacers in the inner spacer recesses;
forming an epitaxial feature in the source/drain trench;
after the forming of the epitaxial feature, removing the dummy gate stack;
releasing the channel layers in the channel region as a plurality of channel members;
forming a gate structure wrapping around each of the channel members; and
after the forming of the gate structure, performing an ion implantation to increase a dopant concentration of a dopant in the epitaxial feature.

2. The method of claim 1, wherein the dopant is an n-type dopant.

3. The method of claim 2, wherein the dopant is phosphorus.

4. The method of claim 1, further comprising:
depositing a dielectric layer over the epitaxial feature;
etching through the dielectric layer to form a hole exposing a top surface of the epitaxial feature; and
prior to the performing of the ion implantation, depositing a liner along sidewalls of the hole.

5. The method of claim 4, wherein the liner is a titanium layer.

6. The method of claim 1, wherein the ion implantation uses phosphorus dimer.

7. The method of claim 1, wherein the dopant concentration has a first peak located above a top surface of a top second one of the channel members.

8. The method of claim 7, wherein the dopant concentration has a second peak located between the top surface and a bottom surface of the top second one of the channel members.

9. The method of claim 1, wherein the dopant concentration in a bottom portion of the epitaxial feature is at least one magnitude lower than in a top portion of the epitaxial feature.

10. The method of claim 1, wherein the dopant concentration at a same depth of the epitaxial feature is substantially same.

11. A method, comprising:
forming a plurality of channel members disposed over a fin-shape substrate;
forming a plurality of inner spacers interleaving the channel members;
forming an epitaxial feature abutting the channel members;
forming a gate structure wrapping around each of the channel members; and
after the forming of the gate structure, increasing a dopant concentration in the epitaxial feature.

12. The method of claim 11, wherein the increasing of the dopant concentration includes a phosphorus ion implantation process.

13. The method of claim 11, wherein the dopant concentration has a peak above about 1×10²² atoms/cm³.

14. The method of claim 13, wherein the peak is located above a bottom surface of a top second one of the channel members.

15. The method of claim 13, wherein the dopant concentration has another peak in a depth lower than where the peak locates.

16. The method of claim 11, wherein prior to the increasing of the dopant concentration, the epitaxial feature is substantially undoped.

17. The method of claim 11, wherein the epitaxial feature includes a first epitaxial layer abutting the channel members and a second epitaxial layer abutting the inner spacers, wherein the first and second epitaxial layers located at a same depth of the epitaxial feature have a substantially same dopant concentration.

18. A semiconductor device, comprising:
a plurality of channel members disposed over a substrate;
a plurality of inner spacers interleaving the channel members;
a gate structure wrapping around each of the channel members;
a gate spacer layer disposed on sidewalls of the gate structure; and
a source/drain feature abutting the channel members, wherein the source/drain feature has a dopant concentration profile that has a peak located above a top surface of a second one of the channel members from top.

19. The semiconductor device of claim 18, wherein the peak is above about 1×10²² atoms/cm³.

20. The semiconductor device of claim 18, further comprising:
a liner disposed on sidewalls of the gate spacer layer, wherein the liner includes a same dopant as in the source/drain feature.
